(19) United States
(12) Patent Application Publication
(10) Pub. No.: US 2026/0271424 A1
(43) Pub. Date: Sep. 10, 2026

(54) SEMICONDUCTOR PHOTO DETECTOR AND SEMICONDUCTOR DEVICE

(71) Applicant: NTT, Inc., Tokyo (JP)

(72) Inventors: Tatsuro Hiraki, Musashino-shi, Tokyo (JP); Yoshiho Maeda, Musashino-shi, Tokyo (JP); Shinji Matsuo, Musashino-shi, Tokyo (JP)

(21) Appl. No.: 18/869,508

(22) PCT Filed: May 31, 2022
(86) PCT No.: PCT/JP2022/022090

§ 371 Date: Nov. 26, 2024

(51) Int. Cl. H10F 77/124; H01S 5/026; H10F 30/22; H10F 77/14

(52) U.S. Cl. CPC H10F 77/124; H01S 5/0262; H10F 30/22; H10F 77/146

(57) ABSTRACT

A semiconductor photodetector includes cladding layers, a III-V compound semiconductor layer, an absorption layer made of a III-V compound semiconductor, a p-type layer and an n-type layer made of a III-V compound semiconductor, and electrodes. The absorption layer consists of a non-doped absorption layer made of a non-doped III-V compound semiconductor, a p-type absorption layer formed in a region where the absorption layer and the p-type layer are in contact and an n-type absorption layer formed in a region where the absorption layer and the n-type layer are in contact. The non-doped absorption layer has an absorption edge wavelength shorter than a wavelength of incident light.

### TECHNICAL FIELD

The present invention relates to a semiconductor photodetector.

### BACKGROUND ART

Integration of III-V compound semiconductors on a Si optical waveguide circuit is a key technology for reducing sizes and costs of optical communication transceivers including lasers. Laser has been implemented on a Si optical waveguide circuit using a technology such as direct bonding of a III-V semiconductor material onto a Si substrate.

In recent years, III-V compound semiconductors on Si substrates have gained attention as materials not only for producing lasers but also for producing high-speed and high-efficiency external modulators and photodetectors. Particularly, a photodetector fabricated by bonding a thin InP-based material onto a Si substrate can easily have higher speed due to its extremely small device capacitance and strong optical confinement factor. For a thin-film InP-based photodetector disclosed in Non Patent Literature 1, a core indicating a high absorption coefficient in a communication wavelength band is embedded in an InP thin film, and the InP on both sides of the core is doped with donors and acceptors, forming a lateral diode. Accordingly, device capacitance becomes smaller than that of a conventional III-V semiconductor device in which p-i-n junctions are formed perpendicular to the substrate, facilitating the implementation of high-speed photodetectors.

To achieve both high sensitivity and high speed of a waveguide-coupled thin film photodetector disclosed in Non Patent Literature 1, it is necessary to shorten the device while increasing optical confinement in the absorption layer. However, the increased optical confinement in the absorption layer requires a wide core width, and further, the greater the core width becomes, the longer a carrier drift time in the depletion layer becomes. Therefore, even for a thin film device with a small RC band, the maximum value of a 3 dB band is limited by the drift time in the depletion layer. On the other hand, if the core width is made thinner to shorten the drift time, the optical confinement in the absorption layer becomes weaker, and the photodetection sensitivity is decreased. That is, a waveguide-coupled thin-film photodetector with an embedded core has a problem that it is difficult to achieve high speed and high sensitivity at the same time.

### CITATION LIST

### Non Patent Literature

Non Patent Literature 1: YANNICK BAUMGARTNER, et al., “High-speed CMOS-compatible III-V on Si membrane photodetectors”, Optics Express, Vol. 29, No. 1, pp. 509-516, 2021

### SUMMARY OF INVENTION

### Technical Problem

The present invention has been made to solve the above problem, and an object thereof is to provide a semiconductor photodetector capable of achieving both high speed and high sensitivity.

### Solution to Problem

A semiconductor photodetector according to the present invention includes: a first cladding layer formed on a substrate; a III-V compound semiconductor layer formed on the first cladding layer; a second cladding layer formed on the semiconductor layer; an absorption layer made of a III-V compound semiconductor embedded in the semiconductor layer; a p-type layer made of a III-V compound semiconductor formed within the semiconductor layer horizontally next to and in contact with the absorption layer; an n-type layer made of a III-V compound semiconductor formed within the semiconductor layer in contact with the absorption layer on a side opposite to the p-type layer with the absorption layer interposed therebetween; a first electrode e formed to connect to the p-type layer; and a second electrode formed to connect to the n-type layer, wherein the absorption layer includes: a non-doped absorption layer made of a non-doped III-V compound semiconductor; a p-type absorption layer formed in a region where the absorption layer and the p-type layer are in contact; and an n-type absorption layer formed in a region where the absorption layer and the n-type layer are in contact, and wherein the non-doped absorption layer has an absorption edge wavelength shorter than a wavelength of incident light.

### Advantageous Effects of Invention

According to the present invention, the absorption layer consists of the non-doped absorption layer, the p-type absorption layer, and the n-type absorption layer, while the absorption edge wavelength of the non-doped absorption layer is set to be shorter than the wavelength of incident light, whereby it is possible to implement a semiconductor photodetector having high speed and high sensitivity at the same time.

### BRIEF DESCRIPTION OF DRAWINGS

FIG. 1 is a sectional view of a semiconductor photodetector according to a first example of the present invention.

FIG. 2 is a sectional view of a semiconductor photodetector according to a second example of the present invention.

FIG. 3 is a diagram illustrating core width dependency of an optical confinement factor in a conventional semiconductor photodetector.

FIG. 4 is a diagram illustrating core width dependency of an optical confinement factor in the semiconductor photodetector according to the second example of the present invention.

FIG. 5 is a sectional view of a semiconductor photodetector according to a third example of the present invention.

FIG. 6 is a sectional view of a semiconductor device according to a fourth example of the present invention.

### DESCRIPTION OF EMBODIMENTS

### First Example

In order to solve the problem described above, it is necessary to reduce the depletion layer width and achieve high optical confinement at the same time. The present invention satisfies the requirements for reducing the depletion layer width and achieving high optical confinement by injecting donors and acceptors into a portion of the thin film core.

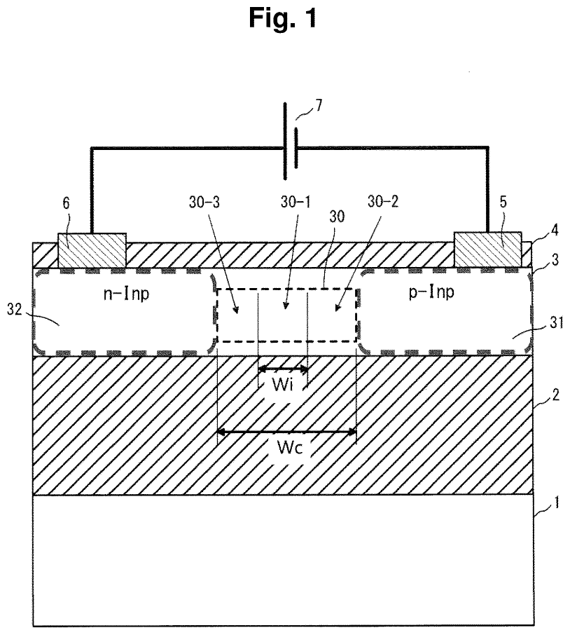

FIG. 1 is a sectional view of a semiconductor photodetector according to the first example of the present invention. A semiconductor photodetector includes a Si substrate 1, a cladding layer 2 made of SiO₂ and formed on the Si substrate 1, a III-V compound semiconductor layer 3 made of InP and formed on the cladding layer 2, a cladding layer 4 made of SiO₂ and formed on the III-V compound semiconductor layer 3, an electrode 5 formed to connect to a p-type layer 31 within the III-V compound semiconductor layer 3, and an electrode 6 formed to connect to an n-type layer 32 within the III-V compound semiconductor layer 3.

An absorption layer 30 serving as a core having a width Wc is embedded in the III-V compound semiconductor layer 3. Furthermore, the p-type layer 31 made of p-type InP and formed next to the absorption layer 30 and in contact with the absorption layer 30 in a horizontal direction (lateral direction in FIG. 1) perpendicular to a lamination direction (vertical direction in FIG. 1) of the cladding layer 2, the III-V compound semiconductor layer 3, and the cladding layer 4; and the n-type layer 32 made of n-type InP and formed in contact with the absorption layer 30 on the opposite side of the p-type layer 31 with the absorption layer 30 interposed therebetween are formed in the III-V compound semiconductor layer 3.

The absorption layer 30 consists of: a non-doped absorption layer 30-1 made of a non-doped III-V compound semiconductor with a width Wi (Wc>Wi); a p-type absorption layer 30-2 formed between the non-doped absorption layer 30-1 and the p-type layer 31 and in contact with the non-doped absorption layer 30-1 and the p-type layer 31, and made of a III-V compound semiconductor into which acceptors are injected; and an n-type absorption layer 30-3 formed between the non-doped absorption layer 30-1 and the n-type layer 32 and in contact with the non-doped absorption layer 30-1 and the n-type layer 32, and made of a III-V compound semiconductor into which donors are injected.

As illustrated in FIG. 1, a distance over which the carriers drift becomes Wi denoted in FIG. 1 when a power source 7 is connected to the electrodes 5 and 6 and a reverse bias is applied to the semiconductor photodetector. Therefore, it is possible to reduce a drift time regardless of the core width Wc by controlling the reverse bias voltage to control the carrier profile.

In the structure of the present example (Wc>Wi), the optical confinement factor for the non-doped absorption layer width is larger than that in the conventional structure (Wc=Wi). Accordingly, it is possible to increase optical confinement even in a structure having a non-doped absorption layer width with a short carrier drift time, and also to achieve both high sensitivity and high speed in the present example.

If the structure of the absorption layer 30 is formed of a material with a small bandgap such as an InGaAs core, which is widely used in the communication wavelength band, slow carriers are generated in doped regions since light is also absorbed in the doped regions (p-type absorption layer 30-2 and n-type absorption layer 30-3). This limits the optical-to-electrical (O-E) band.

Therefore, in the present example, an absorption edge wavelength of the material constituting the non-doped absorption layer 30-1 is set to a shorter wavelength side than the wavelength of the incident light. Accordingly, photocarriers are not generated in the doped regions where no electric field is applied. On the other hand, an absorption coefficient increases, and the incident light is selectively absorbed only within the non-doped absorption layer 30-1 by applying a horizontal electric field within the non-doped absorption layer 30-1. With such a structure, it is possible to simultaneously increase the speed and sensitivity of the semiconductor photodetector while suppressing generation of slow carriers in the doped regions in the present example.

In the present example, the material of the absorption layer 30-1 is a non-doped III-V compound semiconductor, but it may also be a III-V compound semiconductor doped at a low concentration so that it is depleted by reverse bias. In this case, a carrier concentration may be adjusted to obtain a desired absorption layer width Wi by applying a reverse bias voltage.

### Second Example

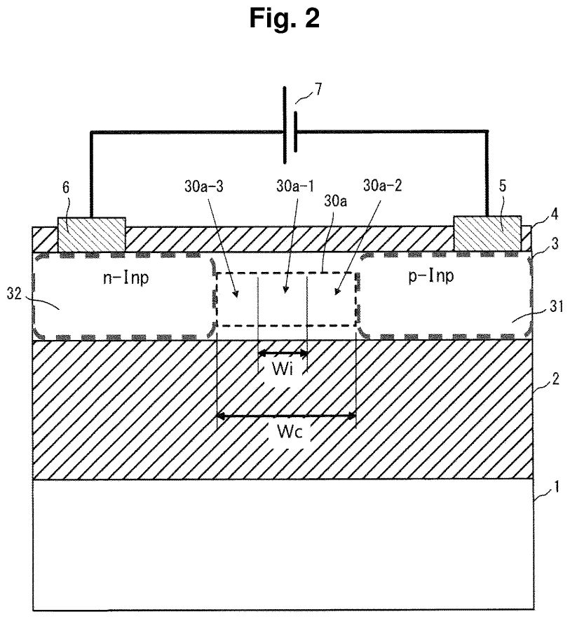

The second example of the present invention will be described. The present example describes a specific example of the first example. FIG. 2 is a cross-sectional view of the semiconductor photodetector according to the present example, and the same components as those in FIG. 1 are denoted by the same reference numerals. A semiconductor photodetector includes a Si substrate 1, a cladding layer 2 made of SiO₂ and formed on the Si substrate 1, a III-V compound semiconductor layer 3 made of InP and formed on the cladding layer 2, a cladding layer 4 made of SiO₂ and formed on the III-V compound semiconductor layer 3, an electrode 5 formed to connect to a p-type layer 31 within the III-V compound semiconductor layer 3, and an electrode 6 formed to connect to an n-type layer 32 within the III-V compound semiconductor layer 3.

An absorption layer 30a serving as a core having a width Wc is embedded in the III-V compound semiconductor layer 3 made of InP and having a thickness of 230 nm. In the present example, an InGaAlAs-based multiple quantum well (MQW) layer is used as the absorption layer 30a. Furthermore, the p-type layer 31 made of p-type InP and formed next to the absorption layer 30a and in contact with the absorption layer 30a along a horizontal direction (lateral direction in FIG. 2) ; and the n-type layer 32 made of n-type InP and formed in contact with the absorption layer 30a on the opposite side of the p-type layer 31 with the absorption layer 30a interposed therebetween are formed in the III-V compound semiconductor layer 3.

The absorption layer 30a consists of: a non-doped absorption layer 30a-1 made of a non-doped MOW layer with a width Wi (Wc>Wi) a p-type absorption layer 30a-2 formed between the non-doped absorption layer 30a-1 and the p-type layer 31 so as to be in contact with the non-doped absorption layer 30a-1 and the p-type layer 31, and made of an MQW layer into which acceptors are injected; and an n-type absorption layer 30a-3 formed between the non-doped absorption layer 30a-1 and the n-type layer 32 so as to be in contact with the non-doped absorption layer 30a-1 and the n-type layer 32, and made of an MQW layer into which donors are injected.

The cladding layers 2 and 4 made of SiO₂ having a smaller refractive index than InP are formed above and below the III-V compound semiconductor layer 3 made of InP, respectively, thereby achieving strong optical confinement.

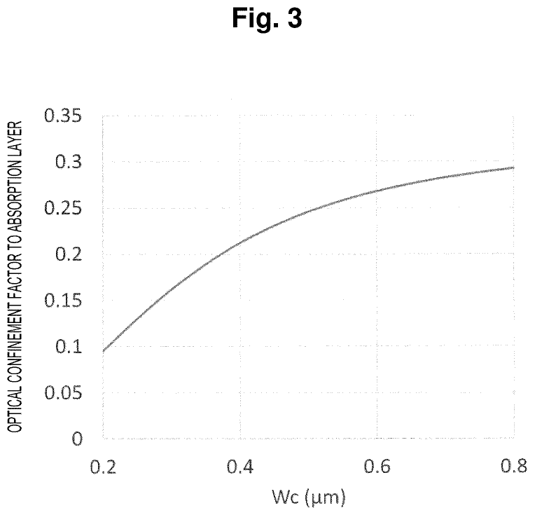

FIG. 3 shows core with dependency of the optical confinement factor in the semiconductor photodetector having the conventional structure in which Wc=Wi, that is, the core is not doped. The optical confinement factor is defined as an optical confinement factor to the well layer embedded in the absorption layer. According to FIG. 3, it can be understood that the optical confinement increases when the core is made thicker, whereas the optical confinement factor decreases significantly when the core is made thinner to shorten the drift time.

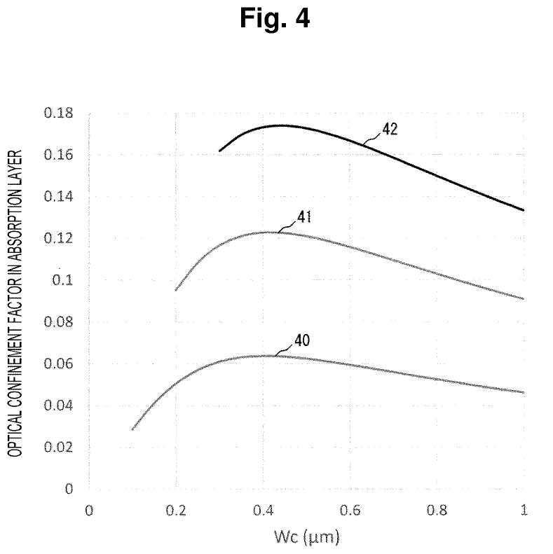

FIG. 4 shows core width dependency of the optical confinement factor in the semiconductor photodetector according to the present example. In FIG. 4, reference numeral 40 denotes the core width dependency of the optical confinement factor in the non-doped absorption layer 30a-1 when the width of the non-doped absorption layer 30a-1 is Wi=100 nm, reference numeral 41 denotes the core width dependency of the optical confinement factor when Wi is 200 nm, and reference numeral 42 denotes the core width dependency of the optical confinement factor when Wi is 300 nm.

In the case where the width Wi is any one of 100 nm, 200 nm or 300 nm in the non-doped absorption layer 30 a-1, it is apparent that the optical confinement factor can be larger when Wc>Wi as in the present example than when Wc=Wi. Since the effect of enhancing optical confinement becomes more significant as the width Wi of the non-doped absorption layer 30a-1 is smaller, the advantage becomes more significant with a device having a shorter drift time.

Further, according to FIG. 4, it can be understood that there is a core width Wc at which the optical confinement factor is maximum, regardless of the width Wi of the non-doped absorption layer 30a-1, which is 100 nm, 200 nm, or 300 nm. When setting the width Wi of the non-doped absorption 30a-1 to a specific value, for example, 100 nm, the core width Wc may be set to about 400 nm so that the optical confinement factor is maximized. Appropriate design of the core width Wc and the width Wi in the non-doped absorption layer 30a-1 enables that both the drift band improvement and high optical confinement are achieved.

As in the first example, the absorption edge wavelength of the non-doped InGaAlAs-based MQW constituting the non-doped absorption layer 30a-1 is set to the shorter wavelength side than the wavelength of the incident light. Accordingly, light is hardly absorbed in the p-type absorption layer 30a-2 into which acceptors are injected and the n-type absorption layer 30a-3 into which donors are injected, so that generation of slow carriers can be suppressed in these doped regions. On the other hand, since a horizontal electric field is applied to the non-doped absorption layer 30a-1 by applying reverse bias to the semiconductor photodetector by the power source 7, only the absorption coefficient within the non-doped absorption layer 30a-1 is selectively increased by the Franz-Keldysh effect. In a case where the MQW layer is used as the absorption layer, it is known that the application of horizontal electric field causes a significant change in absorption coefficient at wavelengths near the absorption edge, and it is possible to increase the absorption coefficient with a relatively low bias voltage.

The semiconductor photodetector according to the present example can be fabricated by the following known processes. First, the InP substrate on which the InP layer, the absorption layer, and the InP layer are grown in order is bonded on the Si substrate 1 on which the SiO₂ film serving as the cladding layer 2 is formed, and the InP substrate is removed. The absorption layer remaining on the SiO₂ film is processed into the shape of a core, and the InP layer formed under the absorption layer is left on the entire surface of the wafer. A non-doped InP layer is newly grown from the InP layer, and the absorption layer 30a processed into the shape of the core is embedded in the InP layer.

Subsequently, the p-type absorption layer 30a-2 and the n-type absorption layer 30a-3 are formed by ion injection or thermal diffusion process. At this time, the diffusion of donors and acceptors into the absorption layer 30a is controlled by controlling the patterning and heat treatment conditions of the p-type absorption layer 30a-2 and the n-type absorption layer 30a-3. Finally, the electrodes 5 and 6 made of metal are formed so that a horizontal electric field can be applied to the non-doped absorption layer 30a-1 via the p-type absorption layer 30a-2 and the n-type absorption layer 30a-3.

In the present invention, when the temperature rises, the band gap of the entire absorption layer becomes smaller, and light absorption is likely to occur even in the doped regions. In order to prevent light absorption in the doped regions even at a high temperature, it is preferable that a difference (detuning amount) between the absorption edge wavelength and the incident light wavelength at room temperature be increased. However, increasing the amount of detuning rises the voltage required to increase the absorption coefficient of the non-doped absorption layer at room temperature. Therefore, it is promising to increase only the detuning amount of the doped regions at room temperature without increasing the detuning amount of the non-doped absorption layer.

When the MOW layer is used as the absorption layer 30a as in the present example, it is possible to increase only the band gap of the doped regions (the p-type absorption layer 30a-2 and the n-type absorption layer 30a-3) by intermixing the MQWs by impurity introduction. That is, the absorption edge wavelength of at least one of the p-type absorption layer 30a-2 and the n-type absorption layer 30a-3 is shorter than the absorption edge wavelength of the non-doped absorption layer 30a-1. According to the present example, the band gap can be selectively increased only in the doped regions without increasing the detuning amount of the non-doped absorption layer 30a-1 at room temperature, thereby suppressing the generation of slow carriers at high temperature.

The temperature of the absorption layer increases not only due to the external environmental temperature but also due to self-heating caused by photocurrent. In particular, since the thin film photodetector has a structure surrounded by SiO₂ having low thermal conductivity, the temperature rise due to self-heating when photocurrent is generated tends to be significant. Furthermore, since the quaternary material constituting the absorption layer has low thermal conductivity, the temperature rise tends to be significant. Therefore, it is desirable to embed the absorption layers 30 and 30a in the InP material with high heat dissipation as in the first example and the present example.

In the present example, the absorption layer 30a-1 is a non-doped MOW layer, but it may also be an MOW layer doped at a low concentration so that it is depleted by reverse bias. In this case, a carrier concentration may be adjusted to obtain a desired absorption layer width Wi by applying a reverse bias voltage.

Further, in the present example, the structure in which the MQW layer is used as the absorption layer has been shown, but the present example is not necessarily limited to MOW, and a bulk layer may be used as the absorption layer. In the case of the bulk layer, the cross-sectional area of the absorption layer is larger than that of MQW, so it is promising for improving electric field shielding resistance when high-intensity light is input. Moreover, it is also possible to use an absorption layer having a quantum wire structure or a quantum dot structure formed by processing MOW into a thin wire pattern.

Further, in the present example, InGaAlAs is used as the material for the absorption layer 30a, but the material is not necessarily limited to InGaAlAs, and an appropriate material may be selected depending on the wavelength of the incident light. For example, an MOW layer having a well layer or barrier layer made of InAs, InGaAs, or InGaAsP may be adopted, or InAlAs forming a high barrier to the well layer in the conduction band may be employed as a barrier layer material of the MQW. Further, when the bulk layer is used as an absorption layer, it may be made of the same material as the well layer of the MQW described above.

In the present example, the thickness of the III-V compound semiconductor layer 3 made of InP is 230 nm, but the thickness is not necessarily limited thereto. However, when a non-doped InP layer is newly epitaxially grown from the InP layer formed under the absorption layer as described above, the thickness of the III-V compound semiconductor layer 3 is desirably equal to or less than the critical film thickness (not more than 430 nm) due to a difference in thermal expansion coefficients between InP and the Si substrate.

### Third Example

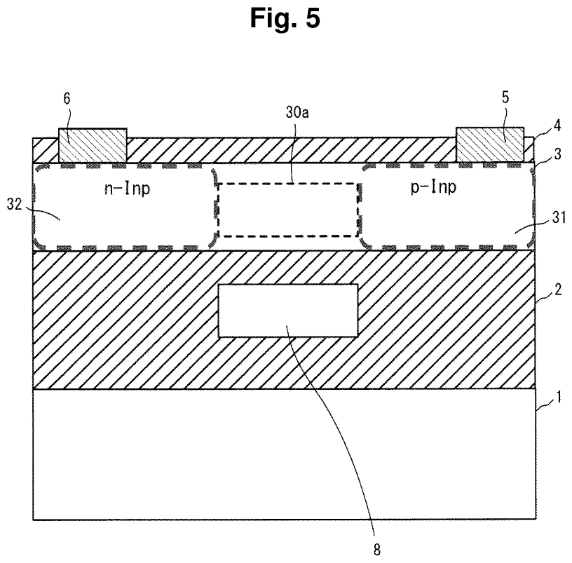

In Examples 1 and 2, as shown in FIG. 5, a structure in which a Si core 8 optically coupled to the absorption layer 30a or 30 of the semiconductor photodetector is formed in the cladding layer 2 is also possible. By coupling the absorption layer 30a or 30 with the low-loss Si core 8, free carrier absorption in the doped regions (p-type absorption layer and n-type absorption layer) is suppressed, and integration with a Si optical waveguide circuit is facilitated. Furthermore, the core material optically coupled to the photoreceiver is not necessarily Si, and may be other low-loss waveguide materials such as SiN or lithium niobate.

### Fourth Example

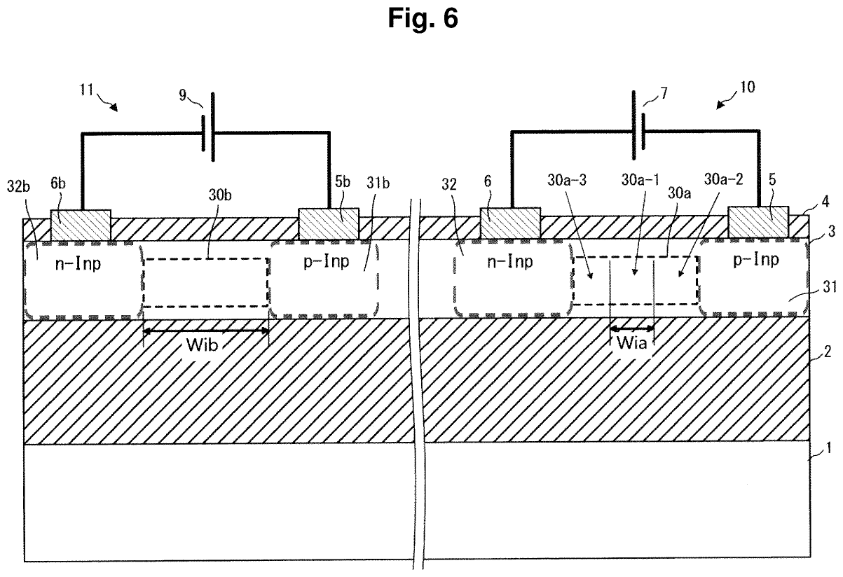

As shown in FIG. 6, it is also possible to integrate a semiconductor laser having an active layer made of the same material as the absorption layer 30a or 30 in Examples 1 and 2 with the semiconductor photodetector. The structure of the semiconductor photodetector 10 is as described in Examples 1 and 2.

A semiconductor laser 11 includes a Si substrate 1, a cladding layer 2 made of SiO₂ and formed on the Si substrate 1, a III-V compound semiconductor layer 3 made of InP and formed on the cladding layer 2, a cladding layer 4 made of SiO₂ and formed on the III-V compound semiconductor layer 3, an electrode 5b formed to connect to a p-type layer 31b within the III-V compound semiconductor layer 3, and an electrode 6b formed to connect to an n-type layer 32b within the III-V compound semiconductor layer 3. As shown in FIG. 6, forward bias is applied to the semiconductor laser 11 by connecting a power source 9 to the electrodes 5b and 6b.

An active layer 30b made of a non-doped III-V compound semiconductor is embedded in the III-V compound semiconductor layer 3. The semiconductor laser 11 includes the active layer 30b having the same thickness and the same material as those of the absorption layer 30a or 30 of the semiconductor photodetector 10 and a III-V compound semiconductor layer 3 having the same thickness as that of the semiconductor photodetector 10, and is common to the semiconductor photodetector 10 in that it has a lateral p-i-n diode structure, so that it can be integrally integrated by the same manufacturing process as that of the semiconductor photodetector 10.

However, the core width and carrier profile are designed differently. The semiconductor photodetector 10 is designed as described above, and the absorption layers 30a and 30 are partially doped, and the core width Wc is designed to maximize optical confinement to the depletion layers (non-doped absorption layers 30a-1 and 30-1) having the width Wia.

On the other hand, in the semiconductor laser 11, since the carrier drift time does not contribute to the performance, the core has a depletion layer width Wib (Wib>Wia) which is wider than that in the semiconductor photodetector 10. As described above, in the present example, for example, it is possible to integrally integrate a high-speed, energy-saving direct modulation laser having strong optical confinement with the semiconductor photodetector.

The semiconductor laser 11 becomes a distributed feedback (DFB) laser by forming a diffraction grating on the surface of the InP layer (III-V compound semiconductor layer 3) shown in FIG. 6.

Further, similarly to the third example, the semiconductor laser 11 also has a low-loss laser structure in which a low-loss core made of, for example, Si that is optically coupled to the active layer 30b is formed in the cladding layer 2. When forming the Si waveguide, it is also possible to form a laser resonator using the Si waveguide layer.

The oscillation wavelength of the semiconductor laser 11 may be designed to be longer than the band edge wavelength of the active layer 30b at room temperature. This is because the thin film laser has a large thermal resistance, and the temperature of the active layer raises significantly due to current injection. By using such a semiconductor laser 11 as a light source of a transmitter, the wavelength of incident light to the semiconductor photodetector 10 including the absorption layer 30a or 30 made of the same material as the active layer 30b becomes longer than the absorption edge wavelength of the absorption layer 30a or 30, and the effect of suppressing light absorption in the doped regions can be obtained as described above.

In the present example, the semiconductor device in which the semiconductor laser and the semiconductor photodetector are integrated has been described, but the present invention is not limited to the semiconductor laser; a semiconductor optical amplifier may be integrated with the semiconductor photodetector.

### Industrial Applicability

The present invention can be applied to a semiconductor device.

### Reference Signs List

1 Si substrate
2, 4 Cladding layer
3 III-V compound semiconductor layer
5, 5b, 6, 6b Electrode
8 Si core
10 Semiconductor photodetector
11 Semiconductor laser
30, 30a Absorption layer
30b Active layer
31, 31b p-Type layer
32, 32b n-Type layer
30-1, 30a-1 Non-doped absorption layer
30-2, 30a-2 p-Type absorption layer
30-3, 30a-3 n-Type absorption layer

1. A semiconductor photodetector, comprising:
a first cladding layer formed on a substrate;
a III-V compound semiconductor layer formed on the first cladding layer;
a second cladding layer formed on the semiconductor layer;
an absorption layer made of a III-V compound semiconductor embedded in the semiconductor layer;
a p-type layer made of a III-V compound semiconductor formed within the semiconductor layer horizontally next to and in contact with the absorption layer;
an n-type layer made of a III-V compound semiconductor formed within the semiconductor layer in contact with the absorption layer on a side opposite to the p-type layer with the absorption layer interposed therebetween;
a first electrode formed to connect to the p-type layer; and
a second electrode formed to connect to the n-type layer, wherein
the absorption layer includes:
a non-doped absorption layer made of a non-doped III-V compound semiconductor;
a p-type absorption layer formed in a region where the absorption layer and the p-type layer are in contact; and
an n-type absorption layer formed in a region where the absorption layer and the n-type layer are in contact, and
the non-doped absorption layer has an absorption edge wavelength shorter than a wavelength of incident light.

2. The semiconductor photodetector according to claim 1, wherein
the absorption layer is made of a multiple quantum well layer.

3. The semiconductor photodetector according to claim 2, wherein
an absorption edge wavelength of at least one of the n-type absorption layer and the p-type absorption layer is shorter than the absorption edge wavelength of the non-doped absorption layer.

4. The semiconductor photodetector according to claim 1, wherein
an optical confinement factor of the non-doped absorption layer varies depending on a total width of the absorption layer, and
the total width of the absorption layer is set such that the optical confinement factor is maximized under conditions where a width of the non-doped absorption layer is set to a specific value.

5. A semiconductor device, comprising:
the semiconductor photodetector according to claim 1; and
a semiconductor laser an active layer of which is made of a material having the same composition as the absorption layer of the semiconductor photodetector, wherein
a width of a depletion layer within the active layer of the semiconductor laser is wider than a width of a depletion layer within the absorption layer of the semiconductor photodetector, and
an emission wavelength of the semiconductor laser is longer than a band edge wavelength of the active layer.

6. A semiconductor device, comprising:
the semiconductor photodetector according to claim 2; and
a semiconductor laser an active layer of which is made of a material having the same composition as the absorption layer of the semiconductor photodetector, wherein
a width of a depletion layer within the active layer of the semiconductor laser is wider than a width of a depletion layer within the absorption layer of the semiconductor photodetector, and
an emission wavelength of the semiconductor laser is longer than a band edge wavelength of the active layer.

7. A semiconductor device, comprising:
the semiconductor photodetector according to claim 3; and
a semiconductor laser an active layer of which is made of a material having the same composition as the absorption layer of the semiconductor photodetector, wherein
a width of a depletion layer within the active layer of the semiconductor laser is wider than a width of a depletion layer within the absorption layer of the semiconductor photodetector, and
an emission wavelength of the semiconductor laser is longer than a band edge wavelength of the active layer.

8. A semiconductor device, comprising:
the semiconductor photodetector according to claim 4; and
a semiconductor laser an active layer of which is made of a material having the same composition as the absorption layer of the semiconductor photodetector, wherein
a width of a depletion layer within the active layer of the semiconductor laser is wider than a width of a depletion layer within the absorption layer of the semiconductor photodetector, and
an emission wavelength of the semiconductor laser is longer than a band edge wavelength of the active layer.
